(19) United States
(12) Patent Application Publication
(10) Pub. No.: US 2011/0260282 A1
(43) Pub. Date: Oct. 27, 2011

(54) SEMICONDUCTOR DEVICE AND MANUFACTURING METHODS

(75) Inventor: Hirohisa Kawasaki, Ballston Spa, NY (US)

(73) Assignee: TOSHIBA AMERICA ELECTRONIC COMPONENTS, INC., Irvine, CA (US)

(21) Appl. No.: 12/766,367

(22) Filed: Apr. 23, 2010

(51) Int. Cl. H01L 29/06; H01L 21/762

(52) U.S. Cl. 257/506; 438/424; 257/E21.546; 257/E29.02

(57) ABSTRACT

Methods of making fins and semiconductor structures containing fins are provided. The methods involve forming a multi-layer structure over fins and isolation materials and performing a multi-stage etching process to remove upper portions of the multi-layer structure and upper portions of isolation materials. Upper portions of the fins are exposed by removing the upper portions of the isolation materials via the multi-stage etching process. A stage of the multi-stage etching process removes an upper layer of the multi-layer structure and an upper portion of the isolation materials, and the stage can be terminated about at the same time when the upper surface of the underlying layer of the multi-layer structure is exposed.

### TECHNICAL FIELD

The following description relates generally to fins and methods of making fins.

### BACKGROUND

As transistor design is improved and evolved, the number of different types of transistors continues to increase. Multi-gate fin field effect transistors (e.g., FinFETs) are developed to provide scaled devices with faster drive currents and reduced short channel effects over planar FETs. One feature of the FinFET is that the conducting channel is wrapped around a thin silicon “fin,” which forms the body of the device. The dimensions of the fin can determine the effective channel length of the device. The term “FinFET” is used generically to describe any fin-based, multi-gate transistor architecture regardless of number of gates. Examples of multi-gate fin field effect transistors include double-gate FinFETs and tri-gate FinFETs.

Double-gate FinFETs are FETs in which a channel region is formed in a thin semiconductor fin. The source and drain regions are formed in the opposing ends of the fin on either side of the channel region. Gates are formed on each side of the thin semiconductor fin, and in some cases, on the top or bottom of the fin as well, in an area corresponding to the channel region. FinFETs are generally a type of double-gate fin FETs in which the fin is so thin as to be fully depleted.

Tri-gate FinFETs have a similar structure to that of double-gate FinFETs. The fin width and height of the tri-gate FinFETs, however, are approximately the same so that gates can be formed on three sides of the channel, including the top surface and the opposing sidewalls. The height to width ratio is generally in the range of 3:2 to 2:3 so that the channel will remain fully depleted and the three-dimensional field effects of a tri-gate FinFET will give greater drive current and improved short-channel characteristics over a planar transistor.

### SUMMARY

The following presents a simplified summary of the information disclosed in the specification in order to provide a basic understanding of some aspects of the disclosed information. This summary is not an extensive overview of the disclosed information, and is intended to neither identify key or critical elements of the disclosed information nor delineate the scope of the disclosed information. Its sole purpose is to present some concepts of the disclosed information in a simplified form as a prelude to the more detailed description that is presented later.

One aspect of the innovation provides methods of forming fins. The methods involve forming a multi-layer structure over fins and isolation materials and performing a multi-stage etching process to remove upper portions of the multi-layer structure and upper portions of isolation materials. Upper portions of the fins are exposed by removing the upper portions of the isolation materials via the multi-stage etching process. The multi-layer structure can contain three layers; a first layer or a lowermost layer over the fins and isolation materials, a second layer or an intermediate layer over the first layer, and a third layer or an uppermost layer over the second layer. When the multi-layer structure contains three layers, a first stage of the multi-stage etching process removes the third layer and an upper portion of the isolation materials, and the first stage can be terminated about at the same time when the upper surface of the second layer is exposed. A second stage of the multi-stage etching process removes the second layer and an upper portion of the remaining isolation materials, and the second stage can be terminated about at the same time when the upper surface of the first layer is exposed.

Another aspect of the innovation relates to semiconductor structures. The semiconductor structures contain a semiconductor substrate containing fins; portions of a multi-layer structure containing three or more layers over the fins; and isolation materials between the fins over the semiconductor substrate, the upper surface of the isolation materials being coplanar with the upper surface of the multi-layer structure.

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

### BRIEF DESCRIPTION OF THE DRAWINGS

FIGS. 1-5 illustrate an exemplary methodology of forming a fin in accordance with an aspect of the subject innovation.

FIG. 6 is a flow diagram of an exemplary methodology of forming a fin in accordance with an aspect of the subject innovation.

FIG. 7 is a flow diagram of an exemplary methodology of forming a shallow trench isolation recess in accordance with an aspect of the subject innovation.

### DETAILED DESCRIPTION

The subject innovation provides fins having improved characteristics of fin height and methods of forming the fins. The fin can be used for semiconductor structures including semiconductor transistors. In one embodiment, the subject innovation provides fins for FinFETs having improved characteristics of fin height and methods of forming the fins for FinFETs. Certain FinFETs have fins and a shallow trench isolation (e.g., STI) between the fins. In such FinFETs, the fin height above the upper surface of the STI is determined in part by a height of the STI or a depth of a recess of in a STI region (e.g., STI recess). The subject innovation can provide a precisely controlled thickness of STI or a precisely controlled depth of a STI recess, and therefore the subject innovation can provide FinFETs having improved characteristics of a substantially uniform fin height.

The subject innovation involves forming a multi-layer structure over fins and insulation materials, and performing a multi-stage etching process to form a STI recess, thereby exposing upper portions of the fins above the STI. Respective etching stages of the multi-stage etching process can be stopped about at the same time when a certain layer of the multi-layer structure is removed or a certain layer of the multi-layer structure is exposed. The fin height above the SIT or the depth of the STI recess can depend on the thicknesses of respective layers of the multi-layer structure and/or on etching selectivity between the material of the multi-layer structure and the material of the STI.

A two or more-stage etching process can be applied until a desired fin height or a desired STI recess depth is obtained. When the multi-layer structure contains three layers, a two-stage etching process can be applied. The first stage can be stopped about at the same time when the third layer or the uppermost layer of the multi-layer structure is etched away. In other words, the first stage can be stopped about at the same time when the material of a layer that underlies the uppermost layer (e.g., second layer) is detected in the etching process. The same schemed can be used in the second and subsequent stages of the etching process. In one embodiment, a first depth of the STI recess after the first stage of the etching process is about half of the final depth of the STI recess.

The stage of the multi-stage etching process can be terminated by any suitable endpointable etch process or endpoint detection technique. In the endpointable etch process or endpoint detection technique, the endpoint of the respective stages of the multi-stage etching process can be controlled in response to detecting that a signal layer or an underlying layer under the layer being etched is exposed in the etching process. The multi-stage etching process does not need to employ a timed etch or a time-based method of etching. Therefore, the subject innovation can provide one or more of the following advantages: the depth variation of STI recess is reduced; the fin height uniformity is increased; and damage to a first layer or the lowermost layer of the multi-layer structure over the fin is prevented or mitigated during the multi-stage etching process because the first layer is covered with another layer of the multi-layer structure during the multi-stage etching process.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

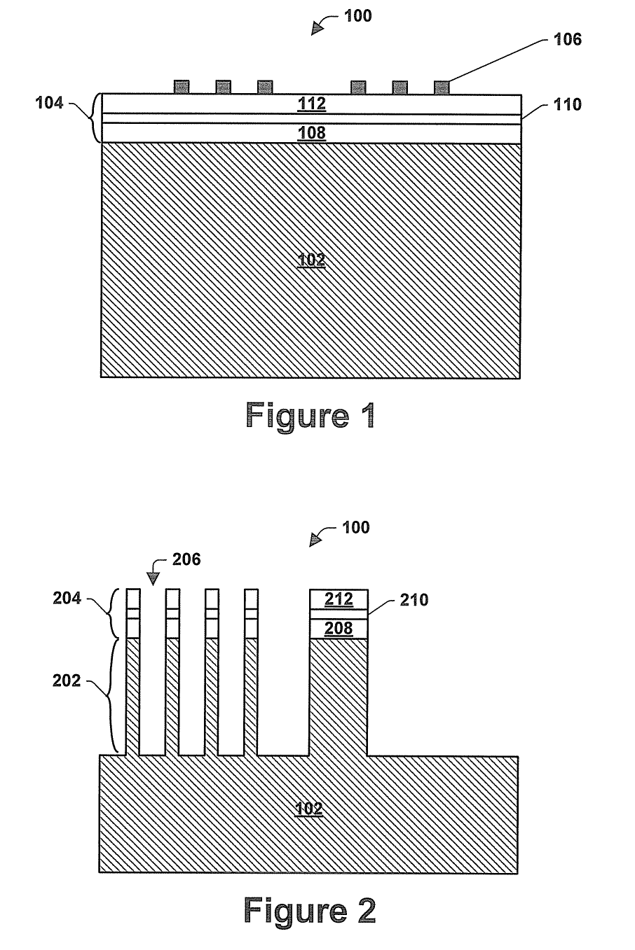

Referring to FIGS. 1 to 5, one of many possible exemplary embodiments of forming a FinFET is specifically illustrated. Although the fins can be used for any suitable semiconductor structure, the subject innovation is hereinafter illustrated and described in the context of exemplary FinFETs. FIG. 1 illustrates a cross sectional view of an intermediate state of an exemplary FinFET 100. The FinFET can contain a relatively thick semiconductor substrate (e.g., bulk semiconductor substrate) 102, a multi-layer structure 104 over the semiconductor substrate, and a patterned resist layer 106 over the multi-layer structure.

The multi-layer structure 104 can contain N layers, where N is an integer which is 3 or more. A first layer or a lowermost layer that is in contact with the semiconductor substrate can be a hard mask layer. The first layer can contain dielectric materials including oxides such as silicon oxide; nitrides such as silicon nitride, silicon rich nitride, and oxygen rich silicon nitride; and the like. The first layer can be formed by chemical vapor deposition (CVD) such as plasma enhanced chemical vapor deposition (PECVD), low-pressure chemical vapor deposition (LPCVD), high-pressure chemical vapor deposition (HPCVD), or the like.

The thicknesses of the layers of the multi-layer structure may vary and the layers independently have any suitable thickness that depends on the desired implementations of the FinFET being fabricated. In one embodiment, the thickness of the first layer is about 10 nm or more and about 100 nm or less. In another embodiment, the thickness of the first layer is about 20 nm or more and about 80 nm or less. In yet another embodiment, the thickness of the first layer is about 30 nm or more and about 60 nm or less. In still yet another embodiment, the thickness of the first layer is about 40 nm.

An Nth layer or an uppermost layer of the multi-layer structure can be a cap layer. The Nth layer can serve as a chemical-mechanical polishing (CMP) stop layer in a subsequent process as described in detail below. The Nth layer can contain dielectric materials including oxides such as silicon oxide; nitrides such as silicon nitride, silicon rich nitride, and oxygen rich silicon nitride; and the like. The Nth layer can be formed by CVD such as PECVD, LPCVD, HPCVD, or the like.

In one embodiment, the thickness of the Nth layer is about 5 nm or more and about 80 nm or less. In another embodiment, the thickness of the Nth layer is about 10 nm or more and about 60 nm or less. In yet another embodiment, the thickness of the Nth layer is about 15 nm or more and about 40 nm or less. In still yet another embodiment, the thickness of the Nth layer is about 30 nm.

The multi-layer structure has one or more intermediate layers between the first layer and the Nth layer. At least one intermediate layer can have a substantially uniform thickness across the semiconductor substrate. The variation of the layer thickness is the range, defined as the difference between the maximum thickness and the minimum thickness of the layer. In one embodiment, the layer has less than about 3% in thickness variation across the semiconductor substrate. In another embodiment, the layer has less than about 2% in thickness variation across the semiconductor substrate. In yet another embodiment, the layer has less than about 1% in thickness variation across the semiconductor substrate. When the layer has a thickness of 10 nm, the layer has less than 0.1 nm in thickness variation.

In one embodiment, the thickness of the intermediate layer is about 1 nm or more and about 30 nm or less. In another embodiment, the thickness of the intermediate layer is about 3 nm or more and about 25 nm or less. In yet another embodiment, the thickness of the intermediate layer is about 5 nm or more and about 20 nm or less. In still yet another embodiment, the thickness of the intermediate layer is about 10 nm.

The intermediate layer can be formed by CVD such as PECVD, LPCVD, HPCVD, or the like. In one embodiment, the intermediate layer is formed by an atomic layer deposition (ALD) process. Typically, the ALD process provides for optimum control of atomic-level thickness and uniformity to the deposited layer. Generally, in an ALD process, each reactant is pulsed sequentially onto the subject layer, typically at deposition temperatures of about 25° C. to about 400° C., which is generally lower than presently used in CVD processes. In one embodiment, the intermediate layer is a metal layer formed by an ALD process. The metal layer contains at least one selected from the group consisting of aluminum (Al), titanium (Ti), zirconium (Zr), hafnium (Hf), and tantalum (Ta).

Although the multi-layer can contain three or more layers, for the purpose of brevity, FIG. 1 illustrate a multi-layer structure containing three layers. In one embodiment, the multi-layer structure contains a first layer 108 or a lowermost layer 108 over the semiconductor substrate, a second layer 110 or an intermediate layer 110 over the first layer, and a third layer 112 or an uppermost layer 112 over the second layer. The third layer can be removed by a first stage of a multi-stage etching process and the second layer can serve as a signal layer that can indicate that the first stage terminates in a subsequent process as described later. The second layer can be removed by a second stage of the multi-stage etching process and the first layer can serve as a signal layer that can indicate that the second stage terminates in a subsequent process as described later. The second layer can have a substantially uniform thickness as described above.

The patterned resist layer 106 can be formed by any suitable technique. For example, the patterned resist layer is formed by optical lithography, sidewall image transfer technique, or the like. Although not shown in FIG. 1, when the patterned resist layer is formed by the sidewall image transfer technique, the patterned resist can be in the shape of a triangle, trapezoid, or the like.

FIG. 2 illustrates removing upper portions of the semiconductor substrate and portions of the multi-layer structure, thereby fowling fins 202 of the semiconductor substrate and portions 204 of the multi-layer structure over the fins between openings 206. Respective portions 204 of multi-layer structure contain portions 208 of the first layer 108, portions 210 of the second layer 110, and portions 212 of the third layer 112. Although four thin fins and one thick fin are shown in FIG. 2, the FinFET 100 can contain any suitable number of fins depending on a type of the transistors being fabricated.

The fins 202 and the portions 204 of the multi-layer structure can be formed by removing portions of the semiconductor substrate and the multi-layer structure. The portions of the semiconductor substrate and the multi-layer structure can be removed by any suitable technique, for example, etching. Portions of the semiconductor substrate and the multi-layer structure can be removed by contacting the semiconductor substrate and the multi-layer structure with any suitable etchant that does not substantially damage and/or remove other components of the FinFET 100. Choice of a suitable process and reagents of etching depends on, for example, the materials of the semiconductor substrate and the multi-layer structure, the width and height of the fins, the desired implementations of the FinFET structure 100 being fabricated, and the like.

Wet etching and/or dry etching containing isotropic etching and/or anisotropic etching can be employed. Examples of wet etchants for silicon of the semiconductor substrate include tetraalkylammonium hydroxides (e.g., tetramethylammonium hydroxide (TMAH)) and alkali metal hydroxides (e.g., a potassium hydroxide (KOH) and cerium hydroxide (CeOH)). Examples of dry etching include reactive ion etching (RIE) using, for example, a mixture gas containing HBr (e.g., HBr and O₂ mixture gas, HBr/NF₃/He and O₂ mixture gas, SF₆, HBr and O₂ mixture gas). The mixture may further include Cl₂.

The fin has any suitable width that depends on the desired implementations of the FinFET structure 100 being fabricated. The width may vary and is not critical to the subject innovation. All of the fins have the same width, or some of or all of the fins have a different width from each other. Although FIG. 2 illustrates the fins having a rectangular cross-section, the fin can have a generally trapezoidal cross-section, or a cross-section with some other shape.

In one embodiment, the width of the fin is about 5 nm or more and about 30 nm or less. In another embodiment, the width of the fin is about 10 nm or more and about 20 nm or less. In yet another embodiment, the width of the fin is about 12 nm or more and about 18 nm or less. In still yet another embodiment, the width of the fin is about 15 nm.

A fin pitch of the fins can be any suitable length that depends on the desired implementations of the FinFET structure 100 being fabricated. The fin pitch may vary and are not critical to the subject innovation. All of the fin pitches have the same length, or some of or all of the fin pitches have a different length from each other. In one embodiment, the fin pitch is about 15 nm or more and about 70 nm or less. In another embodiment, the fin pitch is about 25 nm or more and about 50 nm or less. In yet another embodiment, the fin pitch is about 30 nm or more and about 40 nm or less. In still yet another embodiment, the fin pitch is about 35 nm.

The fin has any suitable height that depends on the desired implementations of the FinFET structure 100 being fabricated. The height may vary and are not critical to the subject innovation. All of the fins have the same height, or some of or all of the fins have a different height from each other. In one embodiment, the height of the fin is about 5 nm or more and about 80 nm or less. In another embodiment, the height of the fin is about 10 nm or more and about 70 nm or less. In yet another embodiment, the height of the fin is about 15 nm or more and about 60 nm or less.

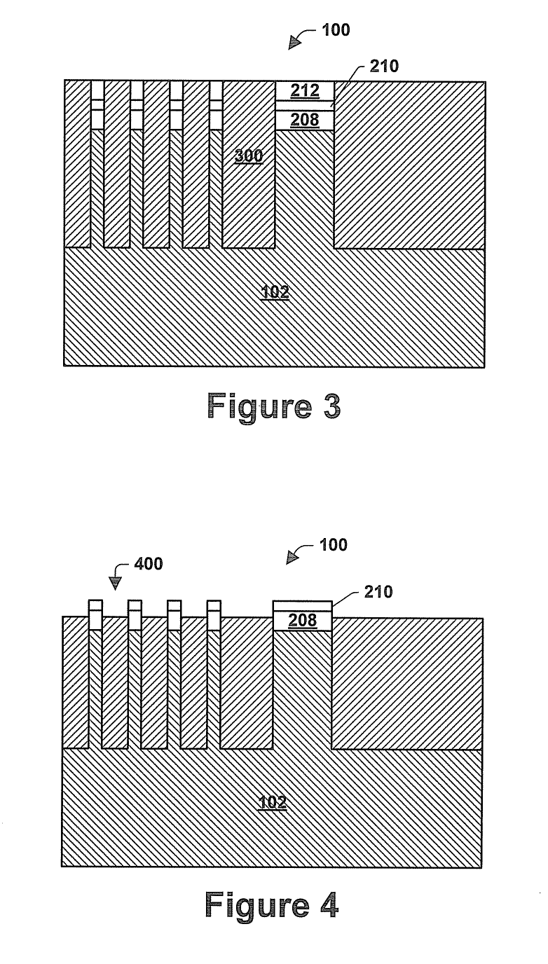

FIG. 3 illustrates forming isolation materials 300 in the openings 206 between the fins over the semiconductor substrate 102. The isolation material 300 can contain any suitable insulating material such as oxides (e.g., silicon oxides) and nitrides (e.g., silicon nitrides). The isolation material can be formed by any suitable technique. For example, an insulating layer (not shown) is formed over the semiconductor substrate 102 and an upper portion of the insulating layer is removed, thereby leaving the isolation material 300 between the fins. The upper surface of the isolation material can be coplanar with the upper surface of the uppermost layer of the multi-layer structure (e.g., the upper surface of the portions 212 of the third layer).

The insulating layer can be formed by any suitable technique including CVD such as PECVD, LPCVD, HPCVD, or the like. An upper portion of the insulating layer can be removed by CMP and/or etching (e.g., RIE). For example, an upper portion of the insulating layer is polished by CMP down to the upper surface of the uppermost layer of the multi-layer structure (e.g., the upper surface of the portions 212 of the third layer).

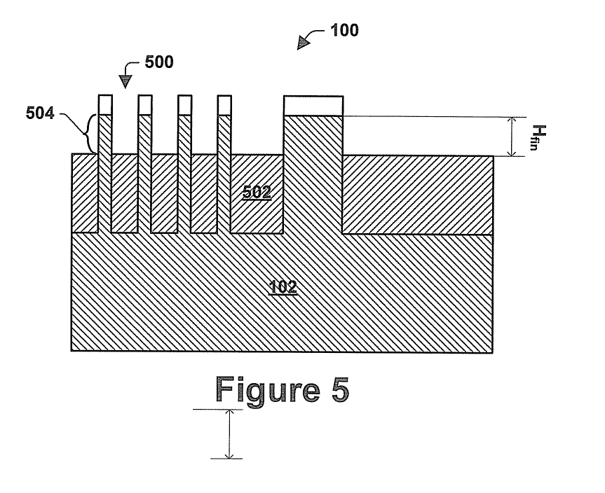

FIGS. 4 and 5 illustrate forming a shallow trench isolation (e.g., STI) 500 by removing an upper portion of the isolation material 300 via a multi-stage etching process. FIGS. 4 and 5 further illustrate exposing an upper portion of the fin 502 above the upper surface of the STI by removing the upper portion of the isolation material 300 via the multi-stage etching process. An intermediate STI recess 400 is formed by one or more stages of the multi-stage etching process as illustrated in FIG. 4. A final STI recess 504 is formed by all the stages of the multi-stage etching process as illustrated in FIG. 5.

The upper portion of the isolation material 300 is removed by a multi-stage etching process. A layer of the multi-layer structure can be used as a signal layer to terminate the stage of the multi-stage etching process. Respective stages of the multi-stage etching process can be terminated about at the same time when the etched layer is removed or a signal layer under the etched layer is exposed.

When the multi-layer structure contains N layers, the multi-stage etching process can involve N−1 stages. A first stage of the multi-stage etching process removes the Nth layer or the uppermost layer of the multi-layer structure to expose an N−1th layer, and the first stage terminates about at the same time when the Nth layer is removed and an upper surface of an N−1th layer is exposed. A second stage of the multi-stage etching process removes an N−1th layer of the multi-layer structure to expose an N−2th layer, and the second stage terminates about at the same time when the N−1th layer is removed and an upper surface of an N−2th layer is exposed. An N−1th stage of the multi-stage etching process removes a second layer of the multi-layer structure to expose a lowermost layer, and the N−1th stage terminates about at the same time when the second layer is removed and a first layer or an upper surface of a lowermost layer is exposed. In a similar way, a Mth stage of the multi-stage etching process removes the N−M+1th layer of the multi-layer structure, and the Mth stage terminates about at the same time when the N−M+1th layer is removed and an upper surface of an N−Mth layer is exposed, wherein M is an integer which is 1 or more and N−1 or less.

The stage of the multi-stage etching process can be terminated in response to detecting that a signal layer (e.g., an underlying layer) under the etched layer is exposed. A technique to determine when to stop a stage of etching may be referred to as process endpoint detection. Respective stages of the multi-stage etching process can be terminated by any suitable endpointable etch process or endpoint detection technique. In one embodiment, a stage of the multi-stage etching process is stopped using optical emission spectroscopy of reactant gases in an etching chamber. The intensities of spectra emitted by the gases change whenever the electrical and chemical conditions in the system change. Such changes occur when a desired layer is fully etched, exposing the underlying layer. When the etched layer is fully removed, its contribution to the etching system changes, and its spectrum intensity reflects this change. By monitoring these spectral emissions, an endpoint for etching can be determined.

Respective stages of the multi-stage etching process can be stopped based on a detectable indication of a signal layer. A stage of the multi-stage etching process reaches a certain depth of the STI recess at about the same time when the stage removes a layer of the multi-layer structure. In other words, a stage of the multi-stage etching process reaches a certain depth of the STI recess at about the same time when the stage is stopped by endpoint detection techniques. In this manner, a stage of multi-stage etching process can be controlled to avoid over-etching or under-etching the isolation material, as may occur if a timed etch or a time-based method of etching is employed. In addition, the depth of the STI recess can be controlled by the combination of etch selectivity between the layers of multi-layer structure and the isolation material, and the thicknesses of layer of the multi-layer structure, as described in detail below.

Chemically selective etching can be used to etch a certain layer, thereby mitigating and/or preventing damaging or over-etching other layers (e.g., layers under the etched layer). Etching a layer can be well-regulated to control etching and mitigate and/or prevent damage to the underlying layers because of the selectivity of the etching. Consistency in the dimensions of the underlying layers can be increased.

A first stage of the multi-stage etching process removes the Nth layer of the multi-layer structure selectively with respect to an N−1th layer. A second stage of the multi-stage etching process removes an N−1th layer of the multi-layer structure selectively with respect to an N−2th layer. An N−1th stage of the multi-stage etching process removes a second layer of the multi-layer structure selectively with respect to a first layer. In a similar way, an Mth stage of the multi-stage etching process removes the N−M+1th layer of the multi-layer structure selectively with respect to an N−Mth layer, wherein M is an integer which is 1 or more and N−1 or less.

Respective layers can contain any suitable material so that when a certain stage of the multi-stage etching process removes the etched layer, the stage can reach a desired depth of the STI recess. That is, the materials of respective layers can be selected so that there is suitable etch selectivity between the materials of the respective layers and the isolation materials. The materials of the multi-layer structure can have a lower etch rate than the isolation material in a stage of the multi-stage etching process.

The underlying layers can be protected from damage during the etching process. The upper surface of the underlying layer is covered by a layer being etched during the etching stage, and the etching stage is stopped about at the same time when the upper surface of the underlying layer is exposed. The first to N−1th layers are protected from damage during the first stage of the multi-stage etching process that removes an Nth layer. The first to N−2th layers are protected from damage during the second stage of the multi-stage etching process that removes an N−1th layer. In a similar way, the first to N−Mth layers are protected from damage during an Mth stage of the multi-stage etching process that removes an N−M+1th layer, where M is an integer which is 1 or more and N−1 or less. The upper surface of the N−Mth layer is covered by the N−M+1th layer during the Mth stage, and the Mth stage is stopped about at the same time when the upper surface of the N−Mth layer is exposed.

Since the underlying layers can be protected from damage during the stage of the etching process, the underlying layers can retain the original form or shape after the multi-stage etching process. When the underlying layer has a rectangular cross-section before the multi-stage etching process, the underlying layer can retain the rectangular cross-section after the multi-stage etching process. When the underlying layer has a trapezoidal cross-section before the multi-stage etching process, the underlying layer can retain the trapezoidal cross-section after the multi-stage etching process.

At the respective stages of the multi-stage etching process, a layer of the multi-layer structure and an upper portion of the isolation material can be removed by contacting the multi-layer structure and the isolation material with any suitable etchant that does not substantially damage and/or remove other components of the FinFET 100. Choice of a suitable process and reagents of etching depends on, for example, the materials of the multi-layer structure and the isolation material, the depth of the STI recess, the thickness of the multi-layer structure, the desired implementations of the FinFET structure 100 being fabricated. Respective stages of the multi-stage etching process can independently employ wet etching and/or dry etching containing isotropic etching and/or anisotropic etching. Examples of dry etching include RIE.

FIG. 4 illustrates a first stage of the multi-stage etching process that removes the third layer 212 of the multi-layer structure and removes an upper portion of the isolation material 300, thereby forming an intermediate STI recess 400 and exposing the second layer 210. The first stage is terminated by using the second layer 210 as a signal layer, and the first stage is terminated in response to detecting that the second layer is exposed. The first stage terminates about at the same time when the third layer is removed and the upper surface of the second layer is exposed. In one embodiment, the third layer contains silicon nitrides and the isolation material contains silicon oxides.

In one embodiment, an etch selectivity of the third layer to the isolation material is about 1:1.5. This means that the first stage of the multi-stage etching process etches the isolation material about 1.5 times faster than the third layer of the multi-layer structure. When the third layer has a thickness of 40 nm, the intermediate STI recess has an etch depth of about 60 nm at about the same time when the first stage removes the third layer. In this manner, the depth of the intermediate STI recess after the first stage can be controlled by the combination of etch selectivity between the third layer and the isolation material, and the thicknesses of the third layer.

In another embodiment, an etch selectivity of the third layer to the isolation material is about 1:1 or more and about 1:2 or less. In yet another embodiment, an etch selectivity of the third layer to the isolation material is about 1:1.2 or more and about 1:1.8 or less. In still yet another embodiment, an etch selectivity of the third layer to the isolation material is about 1:1.4 or more and about 1:1.6 or less.

The first stage of the multi-stage etching process can removes any suitable amount of upper portion of the isolation material 300. The intermediate STI recess 400 can have any suitable depth. The depth means a vertical distance between the upper surface of the isolation material before the first stage and the upper surface of the isolation material after the first stage. In one embodiment, the intermediate STI recess has a depth of about 30% or more and about 70% or less of a depth of a final STI recess (e.g., a total etched amount of the isolation materials). In another embodiment, the intermediate STI recess has a depth of about 40% or more and about 60% or less of a depth of a final STI recess. In yet another embodiment, the intermediate STI recess has a depth of about 50% of a depth of a final STI recess.

The first layer 208 and the second layer 210 are covered by the third layer 212 during the first stage of the multi-stage etching process, and the first stage is terminated about at the same time when the upper surface of the second layer is exposed. The first layer and second layer are protected from damage during the first stage of the multi-stage etching process during etching the third layer and the upper portion of the isolation material by being covered with the third layer. The first layer is protected from damage during etching the second layer and an upper portion of the remaining isolation materials by being covered with the second layer. When the first layer and second layer have a rectangular cross-section before the first stage, the first and second layers can retain the rectangular cross-section after the first stage. When the first and second layers have a trapezoidal cross-section before the first stage, the first and second layers can retain the trapezoidal cross-section after the first stage. As a result, consistency in the dimensions of the underlying layers can be increased.

FIG. 5 illustrates a second stage of the multi-stage etching process that removes the second layer 210 of the multi-layer structure and further removes an upper portion of the isolation material 300, thereby forming a final STI recess 500 and exposing the first layer 208. FIG. 5 further illustrates forming a STI 502 between the fins 202 and exposing an upper portion 504 of the fin 202. The second stage is terminated by using the first layer 208 as a signal layer, and the second stage is terminated in response to detecting that the first layer is exposed. The second stage terminates about at the same time when the second layer is removed and the upper surface of the first layer is exposed.

In one embodiment, an etch selectivity of the second layer to the isolation material is about 1:6. This means that the second stage of the multi-stage etching process etches the isolation material about 6 times faster than the second layer. When the second layer has a thickness of 10 nm, the etch depth of the STI recess increases by about 60 nm about at the same time when the second stage removes the second layer. In this manner, the depth of the STI recess after the second stage can be controlled by the etch selectivity between the second layer and the isolation material, and/or the thicknesses of the second layer. The height of the upper portion 504 of the fin exposed above the upper surface of the STI after the second stage can be also controlled by the etch selectivity between the second layer and the isolation material, and/or the thicknesses of the second layer.

In another embodiment, an etch selectivity of the second layer to the isolation material is about 1:2 or more and about 1:10 or less. In yet another embodiment, an etch selectivity of the second layer to the isolation material is about 1:4 or more and about 1:8 or less. In still yet another embodiment, an etch selectivity of the second layer to the isolation material is about 1:5 or more and about 1:7 or less.

The first layer 208 is covered by the second layer 210 during the second stage of the multi-stage etching process, and the second stage is terminated about at the same time when the upper surface of the first layer is exposed. The first layer is protected from damage during the second stage of the multi-stage etching process. When the first layer has a rectangular cross-section before the second stage of the multi-stage etching process, the first layer can retain the rectangular cross-section after the second stage. When the first layer has a trapezoidal cross-section before the second stage of the multi-stage etching process, the first layer can retain the trapezoidal cross-section after the second stage. As a result, consistency in the dimensions of the first layers can be increased.

An upper portion 504 of the fin is exposed above the upper surface of the STI 502 by the multi-stage etching process. In one embodiment, the height (H_{fin}) of the fin above the upper surface of the STI is about 10 nm or more and about 100 nm or less. In another embodiment, the height of the fin above the upper surface of the STI is about 20 nm or more and about 80 nm or less. In yet another embodiment, the height of the fin above the upper surface of the STI is about 30 nm or more and about 60 nm or less. In still yet another embodiment, the height of the fin above the upper surface of the STI is about 40 nm.

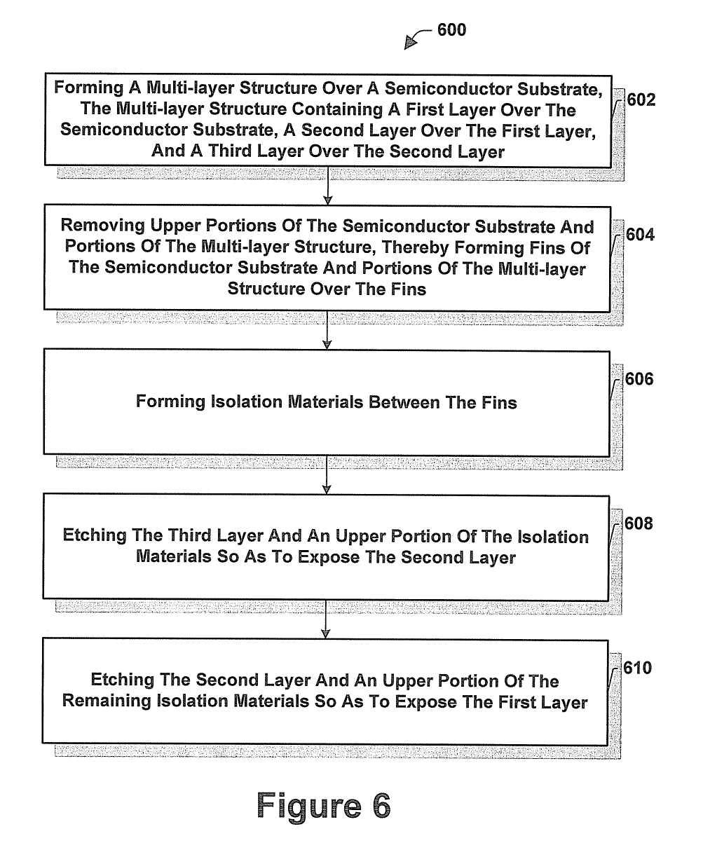

FIG. 6 illustrates an exemplary methodology 600 of forming a fin. At 602, a multi-layer structure is formed over a semiconductor substrate. The multi-layer structure contains a first layer over the semiconductor substrate, a second layer over the first layer, and a third layer over the second layer. At 604, upper portions of the semiconductor substrate and portions of the multi-layer structure are removed, thereby forming fins of the semiconductor substrate and portions of the multi-layer structure over the fins.

At 606, isolation materials are formed between the fins. The upper surface of the isolation materials can be coplanar with the upper surface of the multi-layer structure. At 608, the third layer and an upper portion of the isolation materials are removed by a first stage of a multi-stage etching process so as to expose the second layer. The first etching stage is stopped about at the same time when the second layer is exposed. At 610, the second layer and an upper portion of the remaining isolation materials are removed by a second stage of the multi-stage etching process so as to expose the first layer. The second stage is stopped about at the same time when the first layer is exposed.

Although not shown in FIG. 6, the methodology can involve one or more of the following features. The second layer is formed so that the second layer has less than about 3% in thickness variation across the semiconductor substrate. The second layer is formed by an ALD process. The method involves only an endpointable etch process. In other words, The method involves no timed etch process. A depth of a recess in the isolation material after etching the third layer and the upper portion of the isolation materials is about a 30% or more and about 70% or less of a depth after etching the second layer and an upper portion of the remaining isolation materials. An etch selectivity of the third layer to the isolation material is about 1:1 or more and about 1:2 or less. An etch selectivity of the second layer to the isolation material is about 1:2 or more and about 1:10 or less. The first layer and second layer are protected from damage during etching the third layer and the upper portion of the isolation materials by being covered with the third layer. The first layer is protected from damage during etching the second layer and an upper portion of the remaining isolation materials by being covered with the second layer.

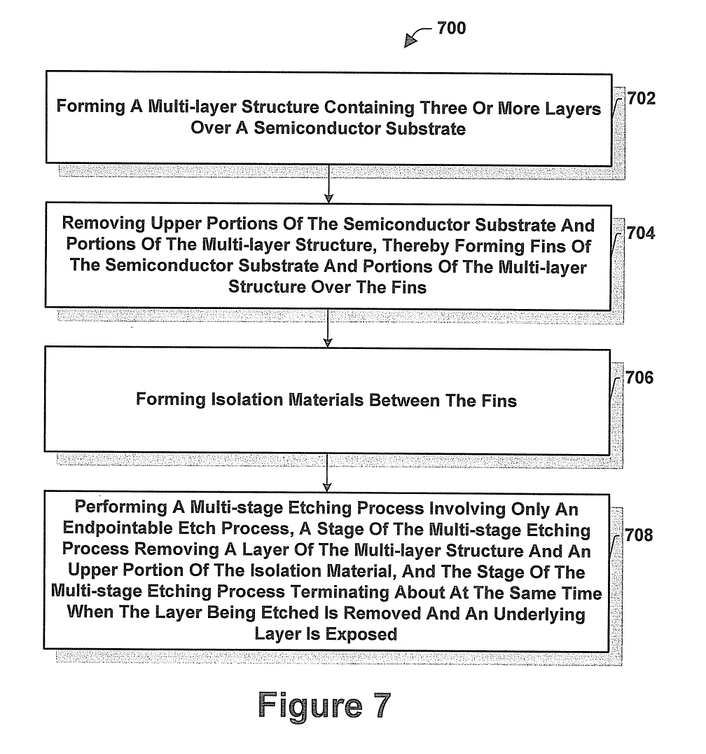

FIG. 7 illustrates an exemplary methodology 700 of method of forming a shallow trench isolation recess. At 702, a multi-layer structure containing three or more layers is formed over a semiconductor substrate. At 704, upper portions of the semiconductor substrate and portions of the multi-layer structure are removed. As a result, fins of the semiconductor substrate and portions of the multi-layer structure over the fins are formed. At 706, isolation materials are formed between the fins. At 708, a multi-stage etching process is performed. The multi-stage etching process involves only an endpointable etch process. A layer of the multi-layer structure and an upper portion of the isolation material are removed by a stage of the multi-stage etching process. The stage of the multi-stage etching process is terminated about at the same time when the layer being etched is removed and an underlying layer is exposed.

Although not shown in FIG. 7, the methodology can involve one or more of the following features. One or more layers of the multi-layer structure are formed so that the layer has less than about 3% in thickness variation across the semiconductor substrate. The one or more layers are formed by an ALD process. The multi-stage etching process involves no timed etch process. The multi-layer structure contains N layers, where N is an integer which is 3 or more, the multi-stage etching process involves M stages, where M is an integer which is 1 or more and N−1 or less, a Mth stage removes an N−M+1th layer of the multi-layer structure, and the Mth stage terminates about at the same time when an N−Mth layer is exposed. In one embodiment, the N is three. An upper surface of the N−Mth layer is covered by the N−M+1th layer during the Mth stage, and the Mth stage is stopped about at the same time when the upper surface of the N−Mth layer is exposed.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

What is claimed is:

1. A method of forming fins, comprising:
forming a multi-layer structure over a semiconductor substrate, the multi-layer structure comprising a first layer over the semiconductor substrate, a second layer over the first layer, and a third layer over the second layer;
removing upper portions of the semiconductor substrate and portions of the multi-layer structure, thereby forming fins of the semiconductor substrate and portions of the multi-layer structure over the fins;
forming isolation materials between the fins, the upper surface of the isolation materials being coplanar with the upper surface of the multi-layer structure;
etching the third layer and an upper portion of the isolation materials so as to expose the second layer; and
etching the second layer and an upper portion of the remaining isolation materials so as to expose the first layer.

2. The method of claim 1, wherein the second layer is formed so that the second layer has less than about 3% in thickness variation across the semiconductor substrate.

3. The method of claim 1, wherein the second layer is formed by an ALD process.

4. The method of claim 1, with the proviso that the method comprises only an endpointable etch process.

5. The method of claim 1, wherein a depth of a recess in the isolation material after etching the third layer and the upper portion of the isolation materials is about a 30% or more and about 70% or less of a depth after etching the second layer and an upper portion of the remaining isolation materials.

6. The method of claim 1, wherein an etch selectivity of the third layer to the isolation material is about 1:1 or more and about 1:2 or less.

7. The method of claim 1, wherein an etch selectivity of the second layer to the isolation material is about 1:2 or more and about 1:10 or less.

8. The method of claim 1, wherein the first layer and second layer are protected from damage during etching the third layer and the upper portion of the isolation materials by being covered with the third layer.

9. The method of claim 1, wherein the first layer is protected from damage during etching the second layer and an upper portion of the remaining isolation materials by being covered with the second layer.

10. A method of forming a shallow trench isolation recess, comprising:
forming a multi-layer structure comprising three or more layers over a semiconductor substrate;
removing upper portions of the semiconductor substrate and portions of the multi-layer structure, thereby forming fins of the semiconductor substrate and portions of the multi-layer structure over the fins;
forming isolation materials between the fins; and
performing a multi-stage etching process comprising only an endpointable etch process, a stage of the multi-stage etching process removing a layer of the multi-layer structure and an upper portion of the isolation material, and the stage of the multi-stage etching process terminating about at the same time when the layer being etched is removed and an underlying layer is exposed.

11. The method of claim 10, wherein one or more layers of the multi-layer structure are formed so that the layer has less than about 3% in thickness variation across the semiconductor substrate.

12. The method of claim 11, wherein the one or more layers are formed by an ALD process.

13. The method of claim 10, wherein the multi-layer structure comprises N layers, where N is an integer which is 3 or more, the multi-stage etching process comprises M stages, where M is an integer which is 1 or more and N−1 or less, a Mth stage removes an N−M+1th layer of the multi-layer structure, and the Mth stage terminates about at the same time when an N−Mth layer is exposed.

14. The method of claim 13, wherein an upper surface of the N−Mth layer is covered by the N−M+1th layer during the Mth stage, and the Mth stage is stopped about at the same time when the upper surface of the N−Mth layer is exposed.

15. The method of claim 14, wherein the N is three.

16. A semiconductor structure, comprising:
a semiconductor substrate comprising fins;
portions of a multi-layer structure comprising three or more layers over the fins, the multi-layer structure comprising one or more layers between a lowermost layer and an uppermost layer, the one or more layers having less than about 3% in thickness variation across the semiconductor substrate; and
isolation materials between the fins over the semiconductor substrate, the upper surface of the isolation materials being coplanar with the upper surface of the multi-layer structure.

17. The semiconductor structure of claim 16, wherein the multi-layer structure comprises a first layer over the fin, a second layer over the first layer, and the third layer over the second layer, the second layer having less than about 3% in thickness variation across the semiconductor substrate.

18. The semiconductor structure of claim 16, wherein one or more layers between a lowermost layer and an uppermost layer of the multi-layer structure are formed by an ALD process.

19. The semiconductor structure of claim 16, wherein an etch selectivity of the third layer to the isolation material is about 1:1 or more and about 1:2 or less.

20. The semiconductor structure of claim 16, wherein an etch selectivity of the second layer to the isolation material is about 1:2 or more and about 1:10 or less.
